(19) United States
(12) Patent Application Publication
(10) Pub. No.: US 2026/0291515 A1
(43) Pub. Date: Sep. 24, 2026

(54) Asynchronous-synchronous Concurrent Two-Stage Analog to Digital Converter and Working Method Therefor

(71) Applicant: JIANGSU GTIC MICROELECTRONICS CO., LTD, Wuxi (CN)

(72) Inventors: Weibo HU, Wuxi (CN); Kefan QIN, Wuxi (CN); Xiang YAN, Wuxi (CN); Haitao CUI, Wuxi (CN); Shangzheng YANG, Wuxi (CN); Fangmin SHI, Wuxi (CN)

(21) Appl. No.: 18/720,646

(22) PCT Filed: Jul. 5, 2023
(86) PCT No.: PCT/CN2023/105937

§ 371 Date: Jun. 12, 2026

(30) Foreign Application Priority Data
Nov. 18, 2022 (CN) 202211445341.0

(51) Int. Cl. H03M 1/74

(52) U.S. Cl. CPC H03M 1/74

(57) ABSTRACT

Disclosed is an asynchronous-synchronous concurrent two-stage digital to analog converter, including digital to analog conversion units and a synchronous control unit. Two stages of digital to analog conversion units are arranged, and the synchronous control unit is arranged between the two stages of digital to analog conversion units. The digital to analog conversion units are asynchronously controlled. The synchronous control unit includes an amplifier and an oscillator. The amplifier is connected to obtain a residual pressure on the first-stage digital to analog conversion unit and is connected to a signal acquisition terminal on the second-stage digital to analog conversion unit. A synchronous clock generated by the oscillator is configured to provide a setup time for the amplifier. The overall processing speed may be significantly increased through asynchronous-synchronous combining schedule control, and the power consumption is reduced.

### TECHNICAL FIELD

The disclosure relates to the technical field of analog to digital conversion, and particularly relates to an asynchronous-synchronous concurrent two-stage analog to digital converter and a working method therefor.

### BACKGROUND

A two-stage analog to digital converter is a common design architecture, with two conventional design thoughts: for the first one, whole sampling and quantifying processes are controlled by using a synchronous clock, and in this process, capacitors have been set; however, it is also needed to wait for a next clock period to compare and set a next-bit capacitor, and this method will limit the sampling speed of the analog to digital converter. For the second one, the whole sampling and quantifying processes are asynchronously controlled: first, a system clock controls an analog to digital converter to sample; after sampling is finished, a comparator starts to compare flipping; the capacitor is set according to a result of the comparator; after the capacitor of each bit is set, an edge signal will be generated and provided to the comparator; and the comparator performs comparison continuously. By using this method, the sampling speed may be increased greatly; however, as a setup time is needed by the amplifier in the two-stage analog to digital converter, and in this case, a lot of delay circuits are needed to provide this time, which results in a lot of power waste.

### SUMMARY

### Technical problems

To overcome deficiencies in the related art, the disclosure provides an asynchronous-synchronous concurrent two-stage analog to digital converter. By controlling the capacitor to flip through an asynchronous clock and providing a setup time for an amplifier through a synchronous clock, the overall processing speed is increased, and the power consumption is reduced.

### Technical solution

To achieve the above object, an asynchronous-synchronous concurrent two-stage digital to analog converter provided by the disclosure includes digital to analog conversion units and a synchronous control unit, where two stages of digital to analog conversion units are arranged, and the synchronous control unit is arranged between the two stages of digital to analog conversion units; the digital to analog conversion units are asynchronously controlled; the synchronous control unit includes an amplifier and an oscillator; the amplifier is connected to obtain a residual pressure on the first-stage digital to analog conversion unit and is connected to a signal acquisition terminal on the second-stage digital to analog conversion unit; and the oscillator is connected to the amplifier, and a synchronous clock generated by the oscillator is configured to provide a setup time for the amplifier.

Further, each of the digital to analog conversion units includes a capacitor array and a digital control circuit, and the digital control circuit controls the capacitor array asynchronously.

Further, the digital to analog conversion unit further includes a switch and a comparator; the switch is arranged on an electric connecting path of the capacitor array in a connected manner; and the comparator is connected to the digital control circuit to compare voltages at input ends of the comparator and to set the capacitor array according to a comparative structure.

Further, the two stages of the digital to analog conversion units are controlled by an asynchronous clock generated by the comparator.

A working method for the asynchronous-synchronous concurrent two-stage digital to analog converter includes the following steps:
step I, sampling, by the first-stage digital to analog conversion unit, an input signal at a sample clock;
step II, after completing the sampling in step I, flipping capacitors in the first-stage capacitor array, and generating, by an asynchronous logic control comparator, a feedback signal after finishing conversion per bit for conversion of a next bit; and after finishing flipping of the one-bit capacitor, starting next comparison, controlling a next-bit capacitor to flip in sequence, and after comparing and setting the capacitor array, collecting, by the amplifier, a residual voltage on the first-stage capacitor array; and
step III, after finishing quantification of the first-stage capacitor array, starting work of the oscillator to provide a synchronous clock to the amplifier, and after experiencing several preset clock periods, starting, by the second-stage capacitor array, to sample signals amplified by the amplifier, where the two stages of capacitor arrays are controlled by the same asynchronous logic; and after finishing quantification of the two stages of capacitor arrays and arriving of a next sample clock, entering, by the two-stage digital to analog converter, a new sample period, and repeating the above process.

### Beneficial Effects

(1) The asynchronous-synchronous concurrent two-stage digital to analog converter provided by the disclosure includes the digital to analog conversion units and the synchronous control unit, where two stages of digital to analog conversion units are arranged, and the synchronous control unit is arranged between the two stages of digital to analog conversion units; the digital to analog conversion units are asynchronously controlled; the synchronous control unit includes the amplifier and the oscillator; the amplifier is connected to obtain the residual pressure on the first-stage digital to analog conversion unit and is connected to the signal acquisition terminal on the second-stage digital to analog conversion unit; and the oscillator is connected to the amplifier, and the synchronous clock generated by the oscillator is configured to provide a setup time for the amplifier; by controlling the capacitor to flip through the asynchronous clock and providing the setup time for an amplifier through the synchronous clock, the overall processing speed is increased, and the power consumption is reduced; and (2) In the asynchronous-synchronous concurrent two-stage digital to analog converter provided by the disclosure, the digital to analog conversion unit includes the capacitor array and the digital control circuit, and the digital control circuit controls the capacitor array asynchronously; the capacitor quantity and scale of the capacitor arrays may be set according to a task requirement of the analog to digital converter, and under asynchronous control, the capacitor matches with the comparator to be set gradually.

### BRIEF DESCRIPTION OF FIGURES

FIG. 1 is a schematic diagram of a binary capacitor array architecture;

FIG. 2 is a schematic diagram of a connection of a single capacitor;

FIG. 3 is a schematic diagram of a common architecture of a two-stage analog to digital converter;

FIG. 4 is a simplified architecture diagram of an amplifier;

FIG. 5 is a schematic diagram of a simplified circuit of a comparator;

FIG. 6 is an overall structural diagram of the asynchronous-synchronous concurrent two-stage digital to analog converter provided by the disclosure;

FIG. 7 is a structural detailed drawing of the asynchronous-synchronous concurrent two-stage digital to analog converter provided by the disclosure;

FIG. 8 is a schematic diagram of a work period of the digital to analog converter provided by the disclosure; and

FIG. 9 is a schematic diagram of a schedule of the digital to analog converter provided by the disclosure.

### REFERENCE NUMERALS IN THE DRAWINGS

1, digital to analog conversion unit; 2, synchronous control unit; 3, amplifier; 4, oscillator; 5, capacitor array; 6, digital control circuit; 7, switch; 8, comparator.

### DETAILED DESCRIPTION

The disclosure will be further described below in conjunction with drawings.

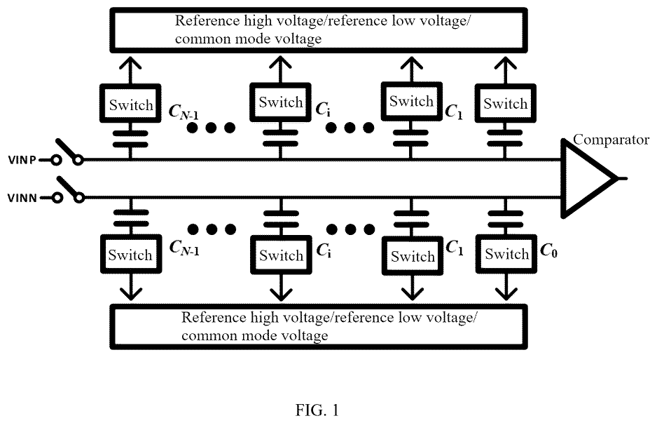

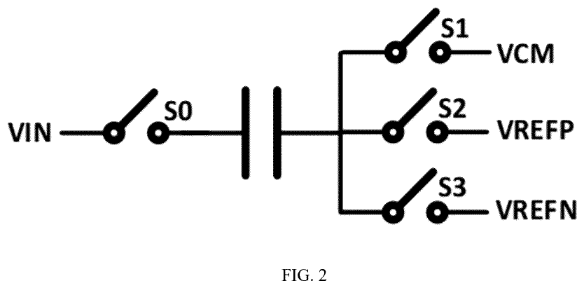

An analog to digital converter samples, quantifies, and encodes input signals with a capacitor array (usually a binary geometric capacitor array) by means of a charge redistribution principle, so as to convert analog signals into digital signals. A conventional binary capacitor array architecture is shown in FIG. 1. The capacitor is set through an inferior plate switch of the capacitor (the inferior plate switch of the capacitor is connected to a reference high level or a reference low level), so that charge flowing is completed. A connecting mode of a single capacitor in the capacitor array is shown in FIG. 2. In a sampling process, a superior plate of the capacitor is connected to an analog input signal VIN through a sampling switch, and the inferior plate is respectively connected to the reference high voltage (VREFP), the reference low voltage (VREFN), and a common mode voltage (VCM) through three set switches. The superior plate is taken as an example in the following sampling process. In the sampling process, a superior plate sampling switch S0 is switched on to sample the analog input signal VIN; and an inferior plate sampling switch S1 is switched on to sample the common mode voltage VCM. After the sampling is completed, the superior plate sampling switch is switched off, and the analog to digital converter starts quantification. First, the comparator compares voltages of both terminals. If the positive terminal voltage of the comparator is higher than the negative terminal voltage, the comparator outputs 1, and on the contrary, the comparator outputs 0. The digital control circuit sets the inferior plate of the capacitor through the set switches S2 and S3 according to a comparison result, so as to initiate a potential change of the superior plate of the capacitor.

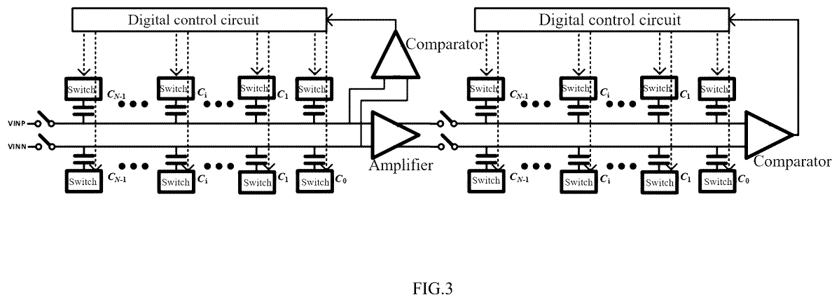

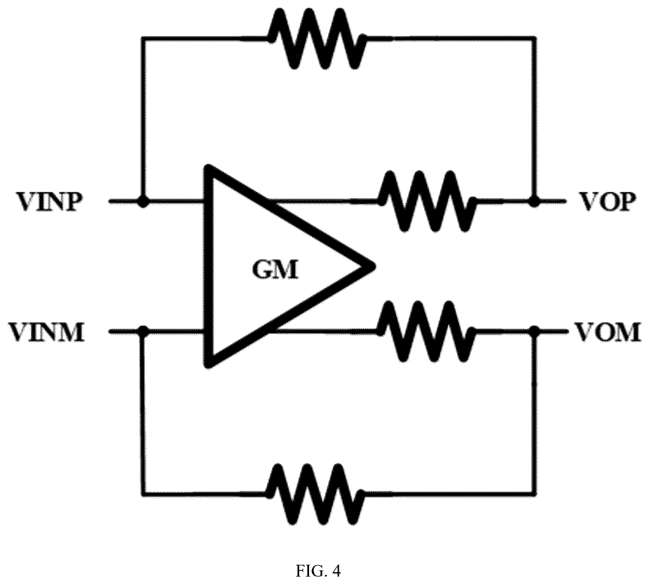

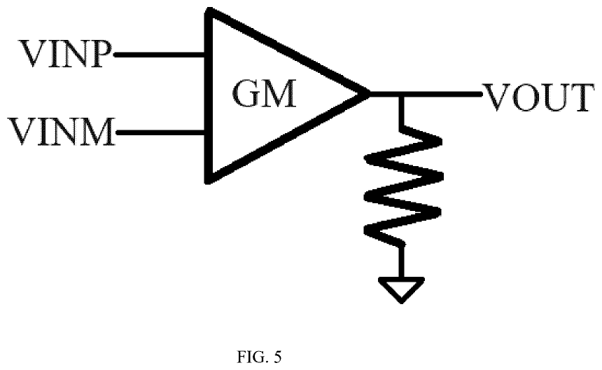

Based on a basic action logic of the above analog to digital converter, a common architecture of a high-precision two-stage analog to digital converter before improvement is shown in FIG. 3. The first-stage capacitor array samples the input analog signal, a remaining residual voltage is taken as an input signal of the amplifier, and the amplifier which amplifies the residual voltage provides the residual voltage to the second stage as the second-stage input voltage. A simplified architecture of a differential output amplifier is shown in FIG. 4. The input signal is converted into a current by inputting gm of geminate transistors, and a function of amplifying the voltage is achieved by amplifying the current. A simplified architecture of the comparator is shown in FIG. 5.

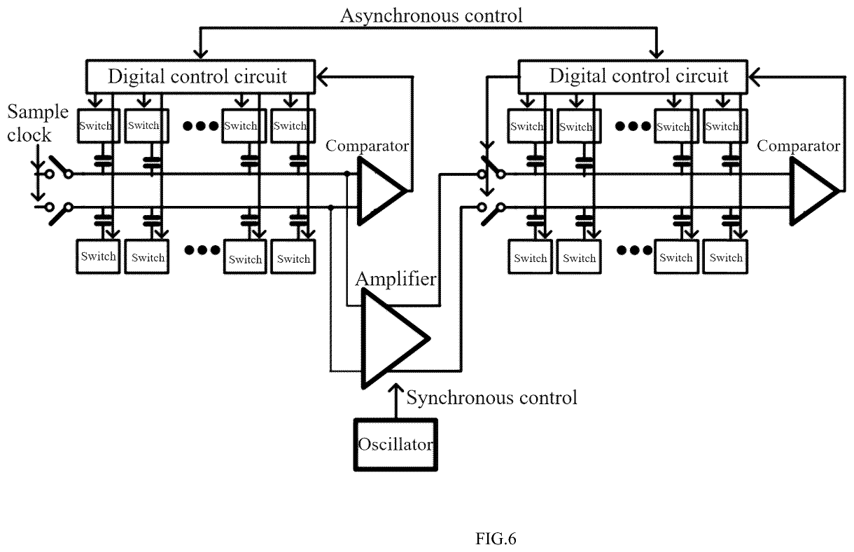

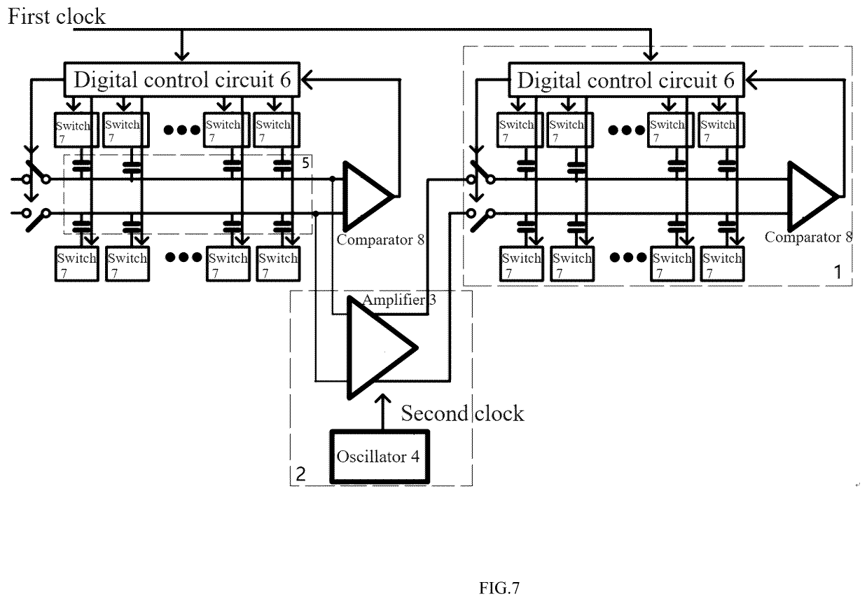

Based on the above architectural basis, referring to FIG. 6 and FIG. 7, an asynchronous-synchronous concurrent two-stage digital to analog converter includes digital to analog conversion units 1 and a synchronous control unit 2, where two stages of digital to analog conversion units 1 are arranged, and the synchronous control unit 2 is arranged between the two stages of digital to analog conversion units 1; the digital to analog conversion units 1 are asynchronously controlled; the synchronous control unit 2 includes an amplifier 3 and an oscillator 4; the amplifier 3 is connected to obtain a residual pressure on the first-stage digital to analog conversion unit 1 and is connected to a signal acquisition terminal on the second-stage digital to analog conversion unit 1; and the oscillator 4 is connected to the amplifier 3, and a synchronous clock generated by the oscillator 4 is configured to provide a setup time for the amplifier 3.

By combining the amplifier 3 with the oscillator 4, synchronous control of signals between the two stages of digital to analog conversion units 1 may be achieved, so that the setup time for the amplifier under asynchronous control is greatly shortened, and the signal transmission efficiency is improved. When the oscillator 4 works, it may repeat oscillating work for 3 periods, so that the first-stage digital to analog conversion unit 1 and the second-stage digital to analog conversion unit are joined efficiently by matching with the setup time for the amplifier. The quantity of the work periods of the oscillator may also be adjusted according to characteristics of processing signals, so as to match with the response speeds of the digital to analog conversion units 1 and the amplifier.

The digital to analog conversion unit 1 includes a capacitor array 5 and a digital control circuit 6, and the digital control circuit 6 controls the capacitor array 5 asynchronously; the digital to analog conversion unit 1 further includes a switch 7 and a comparator 8; the switch 7 is arranged on an electric connecting path of the capacitor array 5 in a connected manner; and the comparator 8 is connected to the digital control circuit 6 to compare voltages at input ends of the comparator 8 and to set the capacitor array 5 according to a comparative structure.

The capacitor quantity and scale of the capacitor arrays 5 may be set according to a task requirement of the analog to digital converter, and under asynchronous control, the capacitor matches with the comparator to be set gradually. The switch is configured to control signal input and output of the digital to analog conversion unit 1.

The two stages of the digital to analog conversion units 1 are controlled by an asynchronous clock generated by the comparator 8.

A working method for the asynchronous-synchronous concurrent two-stage digital to analog converter includes the following steps:
step I, sampling, by the first-stage digital to analog conversion unit 1, an input signal at a sample clock;
step II, after completing the sampling in step I, flipping capacitors in the first-stage capacitor array 5, and generating, by an asynchronous logic control comparator 8, a feedback signal after finishing conversion per bit for conversion of a next bit; and after finishing flipping of the one-bit capacitor, starting next comparison, controlling a next-bit capacitor to flip in sequence, and after comparing and setting the capacitor array, collecting, by the amplifier 3, a residual voltage on the first-stage capacitor array 5; and
step III, after finishing quantification of the first-stage capacitor array 5, starting work of the oscillator 4 to provide a synchronous clock to the amplifier 3, and after experiencing several preset clock periods, starting, by the second-stage capacitor array 5, to sample signals amplified by the amplifier 3, where the two stages of capacitor arrays 5 are controlled by the same asynchronous logic; and after finishing quantification of the two stages of capacitor arrays 5 and arriving of a next sample clock, entering, by the two-stage digital to analog converter, a new sample period, and repeating the above process.

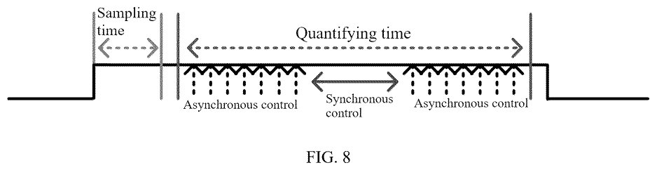

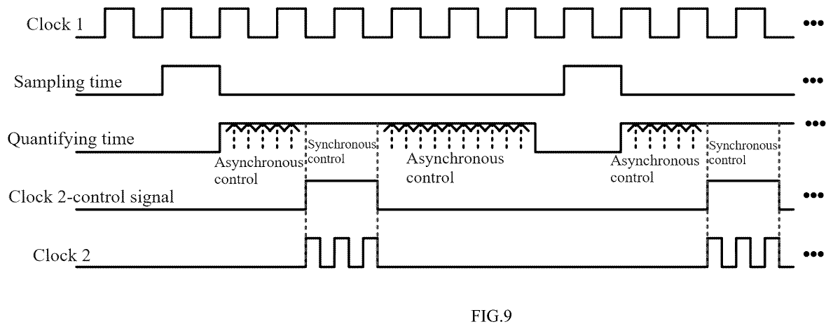

The above working method refers to FIG. 8 and FIG. 9. In the figures, the schedule where the asynchronous clock provided by a first clock and the synchronous clock provided by a second clock work cooperatively is shown. In each work period, asynchronous control of the first-stage digital to analog conversion unit 1, synchronous control of signal amplification, and asynchronous control of the second-stage digital to analog conversion unit 1 are experience, repeating this cycle.

The above is merely the preferred implementations of the disclosure. It shall be noted that a person of ordinary skill in the art can further make several improvements and embellishments without departing from the principle of the disclosure, and these improvements and embellishments shall be regarded within the protection scope of the disclosure.

1. An asynchronous-synchronous concurrent two-stage digital to analog converter, comprising digital to analog conversion units (1) and a synchronous control unit (2), wherein two stages of digital to analog conversion units (1) are arranged, and the synchronous control unit (2) is arranged between the two stages of digital to analog conversion units (1); the digital to analog conversion units (1) are asynchronously controlled; the synchronous control unit (2) comprises an amplifier (3) and an oscillator (4); the amplifier (3) is connected to obtain a residual pressure on the first-stage digital to analog conversion unit (1) and is connected to a signal acquisition terminal on the second-stage digital to analog conversion unit (1); and the oscillator (4) is connected to the amplifier (3), and a synchronous clock generated by the oscillator (4) is configured to provide a setup time for the amplifier (3).

2. The asynchronous-synchronous concurrent two-stage digital to analog converter according to claim 1, wherein each of the digital to analog conversion units (1) comprises a capacitor array (5) and a digital control circuit (6), and the digital control circuit (6) controls the capacitor array (5) asynchronously.

3. The asynchronous-synchronous concurrent two-stage digital to analog converter according to claim 2, wherein the digital to analog conversion unit (1) further comprises a switch (7) and a comparator (8); the switch (7) is arranged on an electric connecting path of the capacitor array (5) in a connected manner; and the comparator (8) is connected to the digital control circuit (6) to compare voltages at input ends of the comparator (8) and to set the capacitor array (5) according to a comparative structure.

4. The asynchronous-synchronous concurrent two-stage digital to analog converter according to claim 1, wherein the two stages of the digital to analog conversion units (1) are controlled by an asynchronous clock generated by the comparator (8).

5. A working method for the asynchronous-synchronous concurrent two-stage digital to analog converter according to claim 1, comprising the following steps:
step I, sampling, by the first-stage digital to analog conversion unit (1), an input signal at a sample clock;
step II, after completing the sampling in step I, flipping capacitors in the first-stage capacitor array (5), and generating, by an asynchronous logic control comparator (8), a feedback signal after finishing conversion per bit for conversion of a next bit; and after finishing flipping of the one-bit capacitor, starting next comparison, controlling a next-bit capacitor to flip in sequence, and after comparing and setting the capacitor array, collecting, by the amplifier (3), a residual voltage on the first-stage capacitor array (5); and
step III, after finishing quantification of the first-stage capacitor array (5), starting work of the oscillator (4) to provide a synchronous clock to the amplifier (3), and after experiencing several preset clock periods, starting, by the second-stage capacitor array (5), to sample signals amplified by the amplifier (3), wherein the two stages of capacitor arrays (5) are controlled by the same asynchronous logic; and after finishing quantification of the two stages of capacitor arrays (5) and arriving of a next sample clock, entering, by the two-stage digital to analog converter, a new sample period, and repeating the above process.
